(19) United States
(12) Patent Application Publication
(10) Pub. No.: US 2026/0303993 A1
(43) Pub. Date: Oct. 1, 2026

(54) IMAGE SENSING DEVICE

(71) Applicant: SK hynix Inc., Gyeonggi-do (KR)

(72) Inventors: Kang Ho KIM, Gyeonggi-do (KR); Gun Hee YUN, Gyeonggi-do (KR); Ho Young PARK, Gyeonggi-do (KR)

(21) Appl. No.: 19/277,403

(22) Filed: Jul. 23, 2025

(30) Foreign Application Priority Data
Mar. 26, 2025 (KR) 10-2025-0038973

(51) Int. Cl. H04N 25/709; H04N 25/532; H04N 25/76

(52) U.S. Cl. CPC H04N 25/709; H04N 25/532; H04N 25/7795

(57) ABSTRACT

An image sensing device for generating image data is disclosed. The image sensing device includes a pixel array including a plurality of pixels arranged in a plurality of rows and a plurality of columns and controlled by a row signal; and a row driver configured to control an activation timing of the row signal based on a control signal. The row signal has a stepped pulse shape in which the row signal rises stepwise based on a first voltage control signal and falls stepwise based on a second voltage control signal.

### CROSS-REFERENCE TO RELATED APPLICATION

This application claims the priority to and benefits of Korean patent application No. 10-2025-0038973, filed on Mar. 26, 2025, which is incorporated by reference in its entirety.

### TECHNICAL FIELD

Embodiments of the present disclosure generally relate to an image sensing device capable of generating image data.

### BACKGROUND

Complementary metal oxide semiconductor (CMOS) image sensors (CISs) are implemented by a CMOS process and have been developed to have lower power consumption, lower costs, and smaller sizes than other competitive products. CMOS image sensors (CISs) have been intensively researched and rapidly come into widespread use. Specifically, CMOS image sensors (CISs) have been developed to have higher image quality than other competitive products, such that the application scope of CMOS image sensors (CISs) has recently been extended to video applications that require higher resolution and higher frame rate as compared to competitive products.

The operation methods for operating these image sensors are classified into a global shutter method and a rolling shutter method. The rolling shutter method is a method in which multiple rows of a pixel array are sequentially exposed and then image signals are sequentially read out. The global shutter method is a method of exposing multiple pixels constituting a pixel array for the same amount of time from the same exposure start timing, sampling signals obtained from the pixels, and then sequentially reading sampled signals of pixels corresponding to multiple rows of the pixel array to output image signals.

However, according to the global shutter method, since the plurality of rows is simultaneously operated during the exposure operation, peak current may occur. In this case, instantaneous power drop may occur in a power supply of a row driver configured to drive the rows, which may increase a settling time of row signals.

### SUMMARY

Various embodiments of the present disclosure relate to an image sensing device capable of reducing peak noise by dispersing peak current of a row driver during a global shutter operation.

In accordance with an embodiment of the present disclosure, an image sensing device may include: a pixel array including a plurality of pixels arranged in a plurality of rows and a plurality of columns and controlled by a row signal; and a row driver configured to control an activation timing of the row signal based on a control signal, wherein the row signal has a stepped pulse shape in which the row signal rises stepwise based on a first voltage control signal and falls stepwise based on a second voltage control signal.

In accordance with another embodiment of the present disclosure, an image sensing device may include: a pixel array including a plurality of pixels arranged in a plurality of rows and a plurality of columns and controlled by a plurality of row signals; and a first driver configured to control a voltage level of a first row signal among the plurality of row signals based on a first voltage control signal and a second voltage control signal; and a second driver configured to control a voltage level of a second row signal among the plurality of row signals based on a third voltage control signal and a fourth voltage control signal, wherein the first voltage control signal and the third voltage control signal are activated at different timings, and the second voltage control signal and the fourth voltage control signal are activated at other different timings.

It is to be understood that both the foregoing general description and the following detailed description of the present disclosure are illustrative and explanatory and are intended to provide further explanation of the disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a block diagram illustrating an example of an image sensing device according to an embodiment of the present disclosure.

FIG. 2 is a circuit diagram illustrating an example of a pixel included in a pixel array shown in FIG. 1 according to an embodiment of the present disclosure.

FIG. 3 is a schematic diagram illustrating a detailed circuit of a row driver shown in FIG. 1 according to an embodiment of the present disclosure.

FIG. 4 is a detailed circuit diagram illustrating a detailed circuit of a transfer driver shown in FIG. 3 according to an embodiment of the present disclosure.

FIG. 5 is a diagram illustrating example operations of the transfer driver shown in FIG. 4 according to an embodiment of the present disclosure.

FIG. 6 is a diagram illustrating an example configuration of the row driver shown in FIG. 1 according to an embodiment of the present disclosure.

FIG. 7 is a diagram illustrating an example configuration of the row driver shown in FIG. 1 according to an embodiment of the present disclosure.

FIG. 8 is a diagram illustrating an example of a global shutter method for use in the image sensing device according to an embodiment of the present disclosure.

### DETAILED DESCRIPTION

The present disclosure provides embodiments of an image sensing device capable of generating image data that may be used in configurations to substantially address one or more technical or engineering issues and to mitigate limitations or disadvantages encountered in other image sensing devices. Embodiments of the present disclosure relate to an image sensing device that can reduce peak noise by dispersing peak current of a row driver during a global shutter operation. The image sensing device according to the embodiments of the present disclosure can reduce the settling time of row signals by reducing peak current of the row signals during the global shutter operation.

Reference will now be made in detail to some embodiments of the present disclosure, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized through the present disclosure.

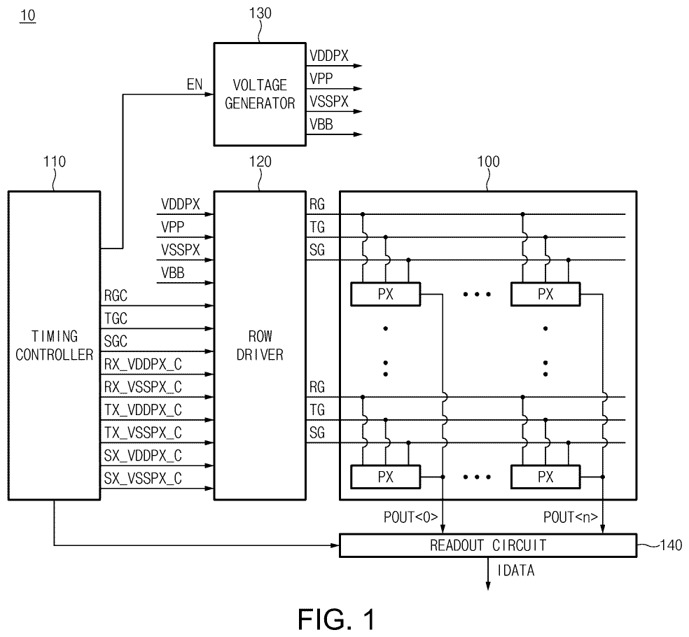

FIG. 1 is a block diagram illustrating an example of an image sensing device 10 according to an embodiment of the present disclosure.

Referring to FIG. 1, the image sensing device 10 may be or include a complementary metal oxide semiconductor image sensor (CIS) for converting an optical signal into an electrical signal.

Referring to FIG. 1, the image sensing device 10 may include a pixel array 100, a timing controller 110, a row driver 120, a voltage generator 130, and a readout circuit 140. The components of the image sensing device 10 illustrated in FIG. 1 are discussed by way of example only, and the present disclosure encompasses numerous other changes, substitutions, variations, alterations, and modifications as would be apparent to one of skill in the art.

The pixel array 100 may include a plurality of pixels (PXs) arranged in rows and columns. In one example, the plurality of pixels (PXs) can be arranged in a two-dimensional (2D) pixel array including rows and columns. In another example, the plurality of pixels can be arranged in a three-dimensional (3D) pixel array. The plurality of pixels (PXs) may convert an optical signal into an electrical signal on a pixel basis or a pixel group basis, and may output pixel signals (POUT<0> to POUT<n>) through a column line.

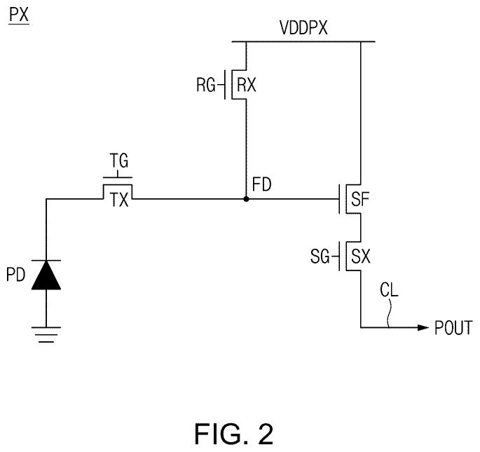

The pixels (PXs) in a pixel group of the pixel array 100 may share at least one internal circuit. The pixel array 100 may receive a reset signal (RG), a transfer signal (TG), and a selection signal (SG) from the row driver 120. Here, the reset signal (RG), the transfer signal (TG), and the selection signal (SG) may be collectively referred to as “row signals”. The corresponding pixel (PX) of the pixel array 100 may perform an operation corresponding to the reset signal (RG), the transfer signal (TG), and the selection signal (SG). The detailed connection structure and operation of the pixel (PX) will be described herein below with reference to FIG. 2.

The timing controller 110 may control clock signals used for the operation of each component of the image sensing device 10, control signals for timing control, and address signals for selecting a row or a column.

According to an embodiment, the timing controller 190 may include a logic control circuit, a phase-locked loop (PLL) circuit, a timing control circuit, a communication interface circuit, and additional circuits or other components.

The timing controller 110 according to the present disclosure may generate a reset control signal (RGC), a transfer control signal (TGC), a selection control signal (SGC), and voltage control signals (RX_VDDPX_C, RX_VSSPX_C, TX_VDDPX_C, TX_VSSPX_C, SX_VDDPX_C, SX_VSSPX_C). Here, the reset control signal (RGC), the transfer control signal (TGC), and the selection control signal (SGC) may n be collectively referred to as “control signals”. In addition, the timing controller 110 may generate an enable signal (EN) for controlling the activation timing of the voltage generator 130.

Here, the term “activation” may indicate an example case where a signal is activated to a logic high level or a logic low level. For example, “activation” may represent an activation state in which a signal transitions from a logic low level to a logic high level, or may represent an activation state in which a signal transitions from a logic high level to a logic low level.

Here, the reset control signal (RGC) may be a signal for controlling the operation of the reset signal (RG). For example, the reset control signal (RGC) may be a signal for controlling the activation timing of the reset signal (RG). The transfer control signal (TGC) may be a signal for controlling the operation of the transfer signal (TG). For example, the transfer control signal (TGC) may be a signal for controlling the activation timing of the transfer signal (TG). The selection control signal (SGC) may be a signal for controlling the operation of the selection signal (SG). For example, the selection control signal (SGC) may be a signal for controlling the activation timing of the selection signal (SG).

The voltage control signals (RX_VDDPX_C, RX_VSSPX_C, TX_VDDPX_C, TX_VSSPX_C, SX_VDDPX_C, SX_VSSPX_C) may be signals for controlling voltage levels of the reset signal (RG), the transfer signal (TG), and the selection signal (SG). For example, the voltage control signals (RX_VDDPX_C, RX_VSSPX_C) may be signals for controlling the voltage level of the reset signal (RG). The voltage control signals (TX_VDDPX_C, TX_VSSPX_C) may be signals for controlling the voltage level of the transfer signal (TG). The voltage control signals (SX_VDDPX_C, SX_VSSPX_C) may be signals for controlling the voltage level of the selection signal (SG).

The row driver 120 may activate the pixel array 100 to perform specific operations on pixels included in the corresponding row based on commands and/or control signals supplied by the timing controller 110. In one embodiment, the row driver 120 may select at least one pixel (PX) arranged in at least one row line of the pixel array 100.

The row driver 120 according to the present disclosure may control the reset signal (RG), the transfer signal (TG) and the selection signal (SG) based on the reset control signal (RGC), the transfer control signal (TGC), the selection control signal (SGC), and the voltage control signals (RX_VDDPX_C, RX_VSSPX_C, TX_VDDPX_C, TX_VSSPX_C, SX_VDDPX_C, SX_VSSPX_C) received from the timing controller 110.

The reset signal (RG), the transfer signal (TG), and the selection signal (SG) generated by the row driver 120 may be driven at either a power-supply voltage (VDDPX) level or a pumping voltage (VPP) level based on the voltage control signals (RX_VDDPX_C, RX_VSSPX_C, TX_VDDPX_C, TX_VSSPX_C, SX_VDDPX_C, SX_VSSPX_C), or may be driven at either a ground voltage (VSSPX) level or a back-bias voltage (VBB) level.

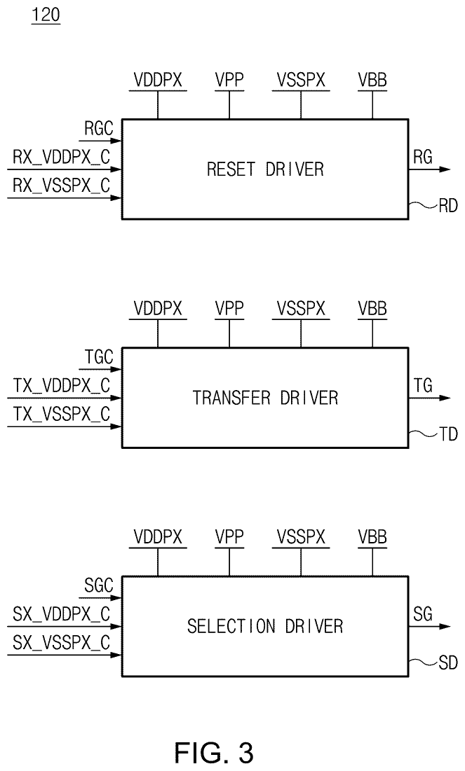

The detailed structure and operation of the row driver 120 will be described herein below with reference to FIGS. 3 to 7.

The voltage generator 130 may boost a voltage received from the outside to generate an internal voltage. In order to improve pixel (PX) characteristics of the pixel array 100, the row driver 120 may use a pumping voltage (VPP) obtained by boosting the power-supply voltage (VDDPX) and a back-bias voltage (VBB) obtained by boosting the ground voltage (VSSPX) as source voltages.

The voltage generator 130 may generate a power-supply voltage (VDDPX) (i.e., a first voltage), a pumping voltage (VPP) (i.e., a second voltage), a ground voltage (VSSPX) (i.e., a third voltage), and a back-bias voltage (VBB) (i.e., a fourth voltage) based on an enable signal (EN). For example, the enable signal (EN) may be generated by the timing controller 110. For example, the voltage generator 130 may include a DC-to-DC (DCDC) converter such as a charge-pump regulator, but the type of the voltage generator is not limited thereto.

Here, the pumping voltage (VPP) may be at a higher level than the power-supply voltage (VDDPX), and the ground voltage (VSSPX) may be at a higher level than the back-bias voltage (VBB). For example, the voltage generator 130 may generate the pumping voltage (VPP) by positively charge-pumping the power-supply voltage (VDDPX). In addition, the voltage generator 130 may generate the back-bias voltage (VBB) by negatively charge-pumping the ground voltage (VSSPX).

An analog reference signal and an image signal generated from each of the pixels (PX) of the row selected by the row driver 120 may be transferred to the readout circuit 140. The reference signal may be an electrical signal that is provided to the readout circuit 140 when a sensing node of a pixel (e.g., a floating diffusion region) is reset, and the image signal may be an electrical signal that is provided to the readout circuit 140 when photocharges generated by the pixel (PX) are accumulated in the sensing node. The reference signal indicating unique reset noise of each pixel and the image signal indicating the intensity of incident light may be generically referred to as pixel signals (POUT<0> to POUT<n>) in accordance with the embodiments described herein.

The readout circuit 140 may be disposed at one side of the pixel array 100, and may generate and store digital data corresponding to the pixel signals (POUT<0> to POUT<n>). For example, the readout circuit 140 may include digital logic configured to generate digital data based on pixel signals (POUT<0> to POUT<n>), and an output buffer configured to store the generated digital data. The digital logic and the output buffer may be collectively referred to as a time-to-digital converter (TDC). The readout circuit 140 may transmit the stored digital data (IDATA) to an image signal processor (not shown) under the control of the timing controller 110.

FIG. 2 is a circuit diagram illustrating an example of the pixel included in the pixel array 100 shown in FIG. 1 according to an embodiment of the present disclosure.

Referring to FIG. 2, the pixel (PX) may be any one of a plurality of pixels included in the pixel array 100. Although FIG. 2 shows only one pixel (PX), other pixels may also have substantially the same structure and operation as those of the pixel (PX).

The pixel (PX) may include a photoelectric conversion element (PD), a transfer transistor (TX), a reset transistor (RX), a floating diffusion region (FD), a source follower transistor (SF), and a selection transistor (SX).

Although the embodiment of pixel (PX) of FIG. 2 is described as including one photoelectric conversion element (PD) for convenience of description, other embodiments are also possible. According to another embodiment, the pixel (PX) may be a shared pixel having a plurality of photoelectric conversion elements. In that instance, a plurality of transfer transistors may be provided corresponding to the plurality of photoelectric conversion elements.

Each of the photoelectric conversion elements (PDs) may generate and accumulate photocharges corresponding to the intensity of incident light. For example, each of the photoelectric conversion elements (PDs) may be implemented as a photodiode, a phototransistor, a photogate, a pinned photodiode, or a combination thereof. If the photoelectric conversion element (PD) is implemented as a photodiode, the photoelectric conversion element (PD) may be a region that is doped with impurities of a second conductivity type (e.g., N-type impurities) in a substrate including impurities of a first conductivity type (e.g., P-type impurities).

The transfer transistor (TX) may be coupled between the photoelectric conversion element (PD) and the floating diffusion region (FD). The transfer transistor (TX) may be turned on or off in response to a transfer control signal (TG). If the transfer transistor (TX) is turned on, photocharges accumulated in the photoelectric conversion element (PD) may be transmitted to the floating diffusion region (FD).

The reset transistor (RX) may be disposed between the floating diffusion region (FD) and the power-supply voltage (VDD) input terminal, and the voltage of the floating diffusion region (FD) can be reset to the power-supply voltage (VDD) in response to a reset control signal (RG).

The floating diffusion region (FD) may accumulate photocharges received from the transfer transistor (TX). For example, the floating diffusion region (FD) may be a region that is doped with impurities of the second conductivity type (e.g., N-type impurities) in a substrate including impurities of the first conductivity type (e.g., P-type impurities).

The source follower transistor (SF) may be coupled between the selection transistor (SX) and the power-supply voltage (VDD) input terminal, may amplify a change in electrical potential of the floating diffusion region (FD) that has received photocharges accumulated in the photoelectric conversion element (PD), and may transmit the amplified result to the selection transistor (SX).

The selection transistor (SX) may be coupled between the source follower transistor (SF) and the column line (CL). The selection transistor (SX) may be turned on by the selection control signal (SEL), so that the selection transistor (SX) can output the electrical signal received from the source follower transistor (SF) as the pixel signal (POUT) through the column line (CL).

The pixel (PX) according to the present disclosure has a 4-T (four-transistor) structure including four transistors. However, the scope of the present disclosure is not limited thereto, and the number of transistors included in the pixel (PX) and the structure of the pixel (PX) may also be sufficiently changed as needed.

FIG. 3 is a schematic diagram illustrating a detailed circuit of the row driver 120 shown in FIG. 1 according to an embodiment of the present disclosure.

Referring to FIG. 3, the row driver 120 may include a reset driver (RD), a transfer driver (TD), and a selection driver (SD).

Here, the reset driver (RD) may control the reset signal (RG) based on the reset control signal (RGC) and the voltage control signals (RX_VDDPX_C, RX_VSSPX_C). The reset driver (RD) may selectively activate or deactivate the reset signal (RG) for the pixels (PX) corresponding to at least one selected row.

The reset driver (RD) may control a voltage level of the reset signal (RG) based on the voltage control signals (RX_VDDPX_C, RX_VSSPX_C). The reset driver (RD) may control the reset signal (RG) to have the power-supply voltage (VDDPX) or the pumping voltage (VPP) level, or may control the reset signal (RG) to have a voltage level of the ground voltage (VSSPX) or the back-bias voltage (VBB) level.

The transfer driver (TD) may control the transfer signal (TG) based on the transfer control signal (TGC) and the voltage control signals (TX_VDDPX_C, TX_VSSPX_C). The transfer driver (TD) may selectively activate or deactivate the transfer signal (TG) for the pixels (PX) corresponding to at least one selected row.

The transfer driver (TD) may control the voltage level of the transfer signal (TG) based on the voltage control signals (TX_VDDPX_C, TX_VSSPX_C). The transfer driver (TD) may control the transfer signal (TG) to have the power-supply voltage (VDDPX) or the pumping voltage (VPP) level, or may control the transfer signal (TG) to have the ground voltage (VSSPX) level or the back-bias voltage (VBB) level.

In addition, the selection driver (SD) may control the selection signal (SG) based on the selection control signal (SGC) and the voltage control signals (SX_VDDPX_C, SX_VSSPX_C). The selection driver (SD) may generate the selection signal (SG) to select at least one row line among the plurality of row lines. In another embodiment, the selection driver (SD) may generate the selection signal (SG) to select one pair of adjacent row lines (i.e., two adjacent row lines) among the plurality of row lines in pairs. The selection driver (SD) may selectively activate or deactivate the selection signal (SG) for the pixels (PX) corresponding to at least one selected row.

The selection driver (SD) may control the voltage level of the selection signal (SG) based on the voltage control signals (SX_VDDPX_C, SX_VSSPX_C). The selection driver (TD) may control the selection signal (SG) to have the power-supply voltage (VDDPX) level or the pumping voltage (VPP) level, or may control the selection signal (SG) to have the ground voltage (VSSPX) level or the back-bias voltage (VBB) level.

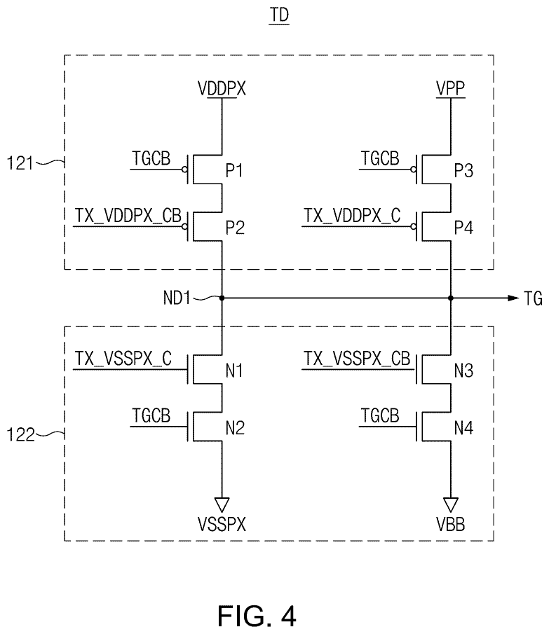

FIG. 4 is a detailed circuit diagram illustrating a detailed circuit of the transfer driver (TD) shown in FIG. 3 according to an embodiment of the present disclosure.

Referring to FIG. 4, the transfer driver (TD) may include a first driver 121 and a second driver 122.

The first driver 121 may drive the transfer signal (TG) at the power-supply voltage (VDDPX) level or the pumping voltage (VPP) level based on the transfer control signal (TGCB) and the voltage control signals (TX_VDDPX_CB, TX_VDDPX_C). In this instance, the transfer control signal (TGCB) may be an inverted signal of the transfer control signal (TGC). The voltage control signal (TX_VDDPX_CB) may be an inverted signal of the voltage control signal (TX_VDDPX_C).

The first driver 121 may include a plurality of P-type metal-oxide-semiconductor (PMOS) transistors (P1~P4). In this instance, the PMOS transistors (P1, P2) may be connected in series between the power-supply voltage (VDDPX) input terminal and the node (ND1). The PMOS transistor (P1) may receive the transfer control signal (TGCB) through a gate terminal thereof. The PMOS transistor (P2) may receive the voltage control signal (TX_VDDPX_CB) through a gate terminal thereof. The PMOS transistors (P3, P4) may be connected in series between the pumping voltage (VPP) input terminal and the node (ND1). The PMOS transistor (P3) may receive the transfer control signal (TGCB) through a gate terminal thereof. The PMOS transistor (P4) may receive the voltage control signal (TX_VDDPX_C) through a gate terminal thereof.

The second driver 122 may drive the transfer signal (TG) at the ground voltage (VSSPX) level or the back-bias voltage (VBB) level based on the transfer control signal (TGCB) and the voltage control signals (TX_VSSPX_C, TX_VSSPX_CB). In this instance, the voltage control signal (TX_VSSPX_CB) may be an inverted signal of the voltage control signal (TX_VSSPX_C).

The second driver 122 may include a plurality of N-type metal-oxide-semiconductor (NMOS) transistors (N1~N4). In this instance, the NMOS transistors (N1, N2) may be connected in series between the node (ND1) and the ground voltage (VSSPX) input terminal. The NMOS transistor (N1) may receive the voltage control signal (TX_VSSPX_C) through a gate terminal thereof. The NMOS transistor (N2) may receive the transfer control signal (TGCB) through a gate terminal thereof. The NMOS transistors (N3, N4) may be connected in series between the node (ND1) and the back-bias voltage (VBB) input terminal. The NMOS transistor (N3) may receive the voltage control signal (TX_VSSPX_CB) through a gate terminal thereof. The NMOS transistor (N4) may receive the transfer control signal (TGCB) through a gate terminal thereof.

The transfer driver (TD) may output the transfer signal (TG) through the node (ND1) through which the first driver 121 and the second driver 122 are connected to each other.

The first driver 121 and the second driver 122 may be selectively (and/or, for example, alternately) operated by the transfer control signal (TGCB). That is, the first driver 121 and the second driver 122 may be operated complementarily by the transfer control signal (TGCB). For example, when the transfer control signal (TGCB) is at a logic low level, the first driver 121 may operate, and when the transfer control signal (TGCB) is at a logic high level, the second driver 122 may operate.

When the transfer control signal (TGCB) is at a logic low level, the PMOS transistors (P1, P3) may be turned on. When the first driver 121 is activated, the PMOS transistors (P2, P4) are selectively turned on according to the voltage control signals (TX_VDDPX_CB, TX_VDDPX_C) so that the voltage level of the transfer signal (TG) can be controlled. For example, when the voltage control signal (TX_VDDPX_CB) is at a logic low level, the PMOS transistor (P2) may be turned on so that the transfer signal (TG) can be driven at the power-supply voltage (VDDPX) level. On the other hand, when the voltage control signal (TX_VDDPX_C) is at a logic low level, the PMOS transistor (P4) may be turned on so that the transfer signal (TG) may be driven at the pumping voltage (VPP) level.

When the transfer control signal (TGCB) is at a logic high level, the NMOS transistors (N2, N4) may be turned on. When the second driver 122 is activated, the NMOS transistors (N1, N3) may be selectively turned on according to the voltage control signals (TX_VSSPX_C, TX_VSSPX_CB) so that the voltage level of the transfer signal (TG) can be controlled. For example, when the voltage control signal (TX_VSSPX_C) is at a logic high level, the NMOS transistor (N1) may be turned on so that the transfer signal (TG) can be driven at the ground voltage (VSSPX) level. On the other hand, when the voltage control signal (TX_VSSPX_CB) is at a logic high level, the NMOS transistor (N3) may be turned on so that the transfer signal (TG) can be driven at the back-bias voltage (VBB) level.

In the embodiment of FIG. 4, the detailed circuit diagram of the transfer driver (TD) is described as an example, but the reset driver (RD) and the selection driver SD may also be implemented in the same or similar configuration, and as such redundant descriptions thereof will herein be omitted for brevity.

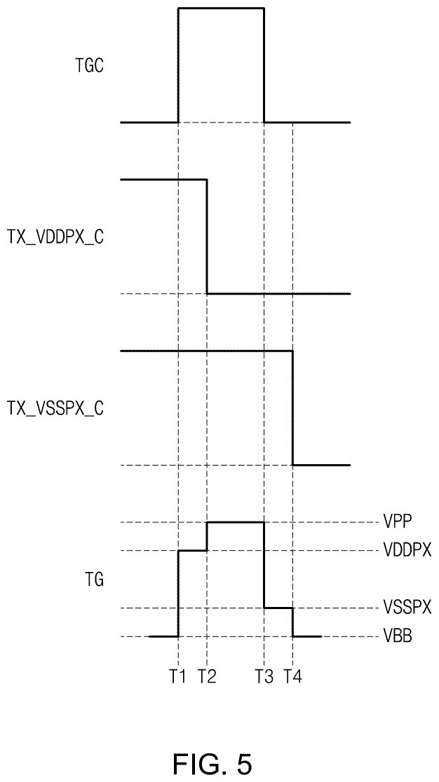

FIG. 5 is a diagram illustrating example operations of the transfer driver (TD) shown in FIG. 4 according to an embodiment of the present disclosure.

Referring to FIG. 5, when the transfer control signal (TGC) transitions to a logic high level at a timing (T1), the transfer control signal (TGCB) becomes a logic low level, so that the first driver 121 can operate. At the timing (T1), the voltage control signal (TX_VDDPX_C) is at a logic high level and the voltage control signal (TX_VDDPX_CB) is at a logic low level, so that the PMOS transistor (P2) can be turned on. Then, the transfer signal (TG) may be driven at the power-supply voltage (VDDPX) level.

Afterwards, at a timing (T2), the voltage control signal (TX_VDDPX_C) transitions to a logic low level and the voltage control signal (TX_VDDPX_CB) becomes a logic high level, so that the PMOS transistor (P4) can be turned on. Then, the transfer signal (TG) may be driven at the pumping voltage (VPP) level.

Then, at a timing (T3), when the transfer control signal (TGC) transitions to a logic low level, the transfer control signal (TGCB) becomes a logic high level, so that the second driver 122 can operate. At the timing (T3), since the voltage control signal (TX_VSSPX_C) is at a logic high level and the voltage control signal (TX_VSSPX_CB) is at a logic low level, the NMOS transistor (N1) can be turned on. Then, the transfer signal (TG) may be driven at the ground voltage (VSSPX) level.

Subsequently, at a timing (T4), the voltage control signal (TX_VSSPX_C) transitions to a logic low level and the voltage control signal (TX_VSSPX_CB) becomes a logic high level, so that the NMOS transistor (N3) can be turned on. Then, the transfer signal (TG) may be driven at the back-bias voltage (VBB) level.

If the voltage level of the transfer signal (TG) rapidly increases to the pumping voltage (VPP) level at the timing (T1), or if the voltage level of the transfer signal (TG) rapidly decreases to the back-bias voltage (VBB) level at the timing (T4), instantaneous peak current may occur. Then, a severe fluctuation may occur in the power source provided to the row driver 120. As a result, the instantaneous peak current may negatively affect the voltage generator 130 that provides the power source to the row driver 120, and the settling time of the row signal may unavoidably increase due to instantaneous power drop.

In the present disclosure, at the timing (T1), the transfer signal (TG) may transition to the power-supply voltage (VDDPX) level, and at the timing (T2), the transfer signal (TG) may increase to the pumping voltage (VPP) level. That is, the rising time at which the transfer signal (TG) is boosted can be controlled stepwise (e.g., in 2 steps). In addition, at the timing (T3), the transfer signal (TG) may transition to the ground voltage (VSSPX) level, and at the time pint (T4), the transfer signal (TG) may decrease to the back-bias voltage (VBB) level. That is, the falling time at which the transfer signal (TG) is boosted can be controlled stepwise (e.g., in 2 steps).

In the present disclosure, the transfer signal (TG) may have a stepped pulse shape in which the transfer signal (TG) rises stepwise based on the voltage control signal (TX_VDDPX_C) and falls stepwise based on the voltage control signal (TX_VSSPX_C). Accordingly, the image sensing device 10 according to the present disclosure can reduce the peak current during the transition of the transfer signal (TG).

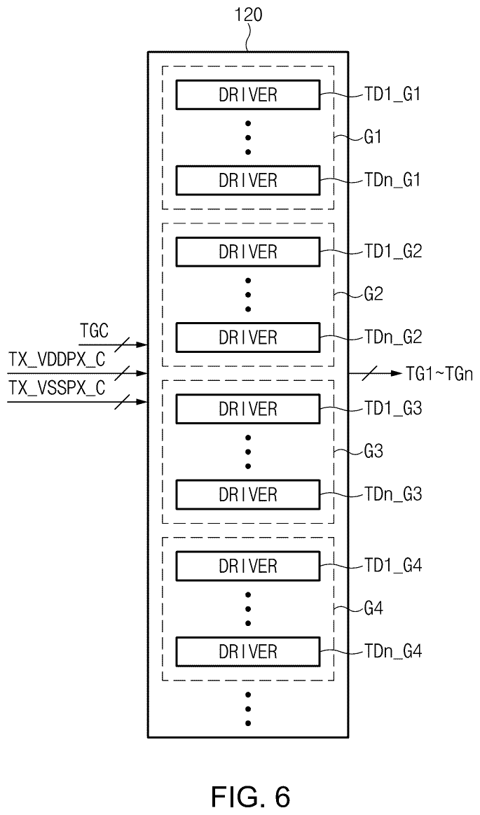

FIG. 6 is a diagram illustrating an example configuration of the row driver 120 shown in FIG. 1 according to an embodiment of the present disclosure.

Referring to FIG. 6, the row driver 120 may include a plurality of drivers (TD1_G1~TDn_G1, TD1_G2~TDn_G2, TD1_G3~TDn_G3, TD1_G4~TDn_G4).

The drivers (TD1_G1~TDn_G1, TD1_G2~TDn_G2, TD1_G3~TDn_G3, TD1_G4~TDn_G4) shown in FIG. 6 may be any one of the reset driver (RD), the transfer driver (TD), and the selection driver (SD) shown in FIG. 3.

In the present disclosure, by way of non-limiting example, the drivers (TD1_G1~TDn_G1, TD1_G2~TDn_G2, TD1_G3~TDn_G3, TD1_G4~TDn_G4) are described as transfer drivers (TD) that activate the transfer signal (TG), and the transfer drivers (TD) will hereinafter be collectively referred to as “drivers”.

The plurality of drivers (TD1_G1~TDn_G1, TD1_G2~TDn_G2, TD1_G3~TDn_G3, TD1_G4~TDn_G4) may be grouped into a plurality of groups (G1~G4). In more detail, the drivers (TD1_G1~TDn_G1) may be grouped into the group (G1), the drivers (TD1_G2~TDn_G2) may be grouped into the group (G2), the drivers (TD1_G3~TDn_G3) may be grouped into the group (G3), and the drivers (TD1_G4~TDn_G4) may be grouped into the group (G4). A plurality of transfer signals (TG1~TGn) may be output through the plurality of drivers (TD1_G1~TDn_G1, TD1_G2~TDn_G2, TD1_G3~TDn_G3, TD1_G4~TDn_G4). Although the present embodiment has disclosed, by way of non-limiting example, that four groups are included in the row driver 120 for convenience of description, other embodiments are also possible, and the number of groups included in the row driver is not limited thereto.

For example, N drivers (TD1_G1~TD1_G1) may be grouped into the group (G1). N drivers (TD1_G2~TDn_G2) may be grouped into the group (G2). N drivers (TD1_G3~TDn_G3) may be grouped into the group (G3). N drivers (TD1_G4~TDn_G4) may be grouped into the group (G4).

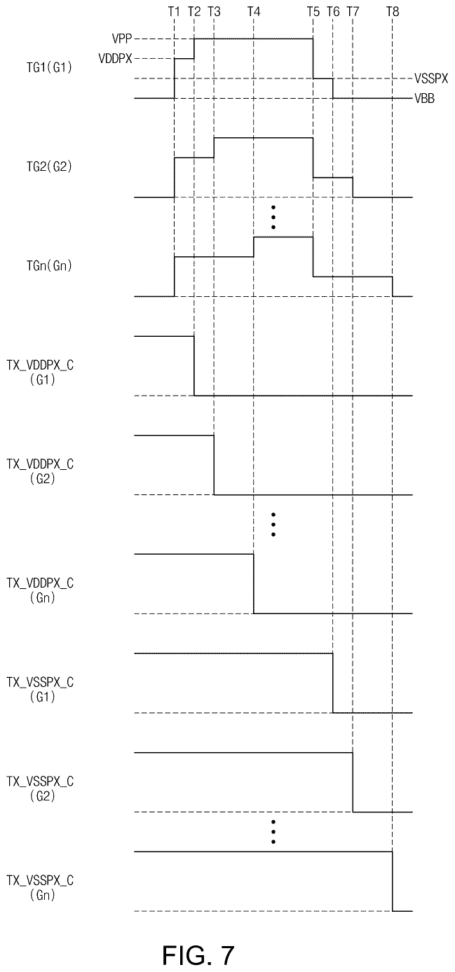

The operations of the row drivers 120 are described herein below with reference to FIG. 7.

FIG. 7 is a diagram illustrating an example configuration of the row driver 120 shown in FIG. 1 in accordance with an embodiment of the present disclosure.

Referring to FIG. 7, the row driver 120 may differently control the voltage boosting timings of the drivers (TD1_G1~TDn_G1, TD1_G2~TDn_G2, TD1_G3~TDn_G3, TD1_G4~TDn_G4) for each group (G1~G4). In more detail, the row driver 120 may differently control the voltage boosting timings of the drivers (TD1_G1~TDn_G1) for the group (G1), the voltage boosting timings of the drivers (TD1_G2~TDn_G2) for the group (G2), the voltage boosting timings of the drivers (TD1_G3~TDn_G3) for the group (G3), and the voltage boosting timings of the drivers (TD1_G4~TDn_G4) for the group (G4).

For example, referring to FIGS. 6 and 7 collectively, the driver (TD1_G1) is described, by way of non-limiting example, as operating in the group (G1), the driver (TD1_G1) is described as operating in the group (G2), the driver (TD1_G3) is described as operating in the group (G3), and the driver (TD1_G4) is described as operating in the group (G4).

At the timing (T1), the first driver 121 may operate when the transfer control signal (TGC) is activated. That is, the first driver 121 may be enabled in the drivers (TD1_G1, TD1_G2, TD1_G3, TD1_G4) for each group (G1~G4). In more detail, the first driver 121 may be enabled in the driver (TD1) for the group (G1), the first driver 121 may be enabled in the driver (TD2) for the group (G2), the first driver 121 may be enabled in the driver (TD3) for the group (G3), and the first driver 121 may be enabled in the driver (TD4) for the group (G4). Then, all of the transfer signals (TG1~TGn) output from the drivers (TD1_G1, TD1_G2, TD1_G3, TD1_G4) may be activated to be driven at the power-supply voltage (VDDPX) level.

Afterwards, at the timing (T2), the voltage control signal (TX_VDDPX_C) of the group (G1) may transition to a logic low level. Then, the transfer signal (TG1) of the group (G1) may be boosted to the pumping voltage (VPP) level. After the transfer signal (TG1) is boosted to the pumping voltage (VPP) level at the timing (T2), the pumping voltage (VPP) level can be maintained for a predetermined time.

Then, at the timing (T3), the voltage control signal (TX_VDDPX_C) of the group (G2) may transition to a logic low level. Then, the transfer signal (TG2) of the group (G2) can be boosted to the pumping voltage (VPP) level. After the transfer signal (TG2) is boosted to the pumping voltage (VPP) level at the timing (T3), the pumping voltage (VPP) level can be maintained for a predetermined time.

Subsequently, at the timing (T4), the voltage control signal (TX_VDDPX_C) of the group (Gn) may transition to a logic low level. Accordingly, the transfer signal (TGn) of the group (Gn) may be boosted to the pumping voltage (VPP) level. After the transfer signal (TGn) is boosted to the pumping voltage (VPP) level at the timing (T4), the pumping voltage (VPP) level may be maintained for a predetermined time.

In this instance, the predetermined time during which the transfer signals (TG1~TGn) are maintained at the pumping voltage (VPP) level may be considered sufficient to drive the transfer transistors (TXs) of the pixel (PX). In this instance, the predetermined time during which the transfer signals (TG1~TGn) are maintained at the pumping voltage (VPP) level (i.e., the predetermined time during which the transfer signals (TG1~TGn) are maintained at the pulse width of the logic high level) may be controlled by the timing controller 110.

Subsequently, at the timing (T5), when the transfer control signal (TGC) is deactivated, the second driver 122 can operate. That is, the second driver 122 may be enabled in the drivers (TD1_G1, TD1_G2, TD1_G3, TD1_G4) for each group (G1~G4). As a result, all of the transfer signals (TG1~TGn) output from the drivers (TD1_G1, TD1_G2, TD1_G3, TD1_G4) may be disabled and driven at the ground voltage (VSSPX) level.

Thereafter, at the timing (T6), the voltage control signal (TX_VSSPX_C) of the group (G1) may transition to a logic low level. Then, the transfer signal (TG1) of the group (G1) can be boosted to the back-bias voltage (VBB) level.

Subsequently, at the timing (T7), the voltage control signal (TX_VSSPX_C) of the group (G2) may transition to a logic low level. Then, the transfer signal (TG2) of the group (G2) can be boosted to the back-bias voltage (VBB) level.

Then, at the timing (T8), the voltage control signal (TX_VSSPX_C) of the group (Gn) may transition to a logic low level. Then, the transfer signal (TGn) of the group (Gn) can be boosted to the back-bias voltage (VBB) level.

In each group (G1~Gn), when the transfer signals (TG1~TGn) are boosted to the pumping voltage (VDD) level at the same time (e.g., at the timing T1) or boosted to the back-bias voltage (VBB) level at the same time (e.g., at the timing T6), instantaneous peak current may occur. In particular, the pumping voltage (VPP) and the back-bias voltage (VBB) generated by the voltage generator 130 may be more vulnerable to instantaneous power drops. Accordingly, the instantaneous peak current may cause a voltage drop in the voltages generated by the voltage generator 130.

Accordingly, the image sensing device (for example, image sensing device 10, described herein above with respect to FIG. 1) according to the present disclosure may differently control the timings at which the transfer signals (TG1~TGn) for each group (G1~Gn) are boosted to the pumping voltage (VPP) level. For example, the row driver 120 may sequentially control the timings at which the transfer signals (TG1~TGn) are activated at the pumping voltage (VPP) level for each group (G1~Gn). Although the present disclosure has disclosed that the transfer signals (TG1~TGn) are sequentially activated at the pumping voltage (VPP) level for convenience of description, other embodiments are also possible, and it should be noted that the timing at which the transfer signals (TG1~TGn) are activated may be optional.

In addition, the image sensing device 10 according to the present disclosure may differently control the timing at which the transfer signals (TG1~TGn) for each group (G1~Gn) are respectively boosted to the back-bias voltage (VBB) level. For example, the row driver 120 may sequentially control the timings at which the transfer signals (TG1~TGn) for each group (G1~Gn) are deactivated to the back-bias voltage (VPP) level. Although the present disclosure has disclosed that the transfer signals (TG1~TGn) are sequentially deactivated to the back-bias voltage (VBB) level for convenience of description, other embodiments are also possible, and it should be noted that the timing at which the transfer signals (TG1~TGn) are deactivated may be optional.

Accordingly, the present disclosure may reduce a peak current caused by the power drop of the boosting voltages (VPP, VBB) by distributing the timing (at which the transfer signals (TG1~TGn) are boosted) for each group (G1~Gn).

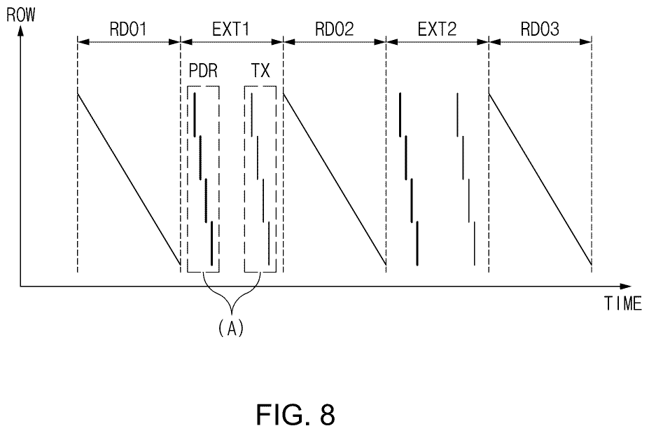

FIG. 8 is a diagram illustrating an example of a global shutter method for use in an image sensing device (for example, image sensing device 10) according to an embodiment of the present disclosure.

Referring to FIG. 8, reset data of a floating diffusion region (FD) may be read before accumulating signal charges during a readout period (RDO1~RDO3). The readout operation of reset data can be performed sequentially from the first row to the last row in the pixel array 100 to read reset data of all pixels (PX). The readout reset data can be transmitted to the readout circuit 140.

In addition, the image sensing device 10 may be driven in a global shutter mode. The global shutter mode (for example, implementing a global shutter method) may include a period (PDR) in which charges accumulated in the floating diffusion region (FD) are reset upon entering each exposure period (EXT1, EXT2). The global shutter mode may include an accumulation period in which the transfer transistor (TX) is turned on upon entering each exposure time (EXT1, EXT2) and photocharges generated by the photoelectric conversion element (PD) are accumulated. Accordingly, in each exposure period (EXT1, EXT2), row signals (e.g., transfer signal TG) may be simultaneously activated for all rows to accumulate photocharges in the photoelectric conversion element (PD).

However, since the global shutter mode enables the plurality of rows to operate simultaneously in the exposure period, peak current may occur. When the multiple rows are activated simultaneously, instantaneous power drop may occur in the power source of the row driver that drives the rows, which may increase the settling time of the row signals.

Accordingly, the image sensing device according to the present disclosure may sequentially activate the voltage control signals (TX_VDDPX_C) for each group (G1~G4) in each exposure period (EXT1, EXT2). Accordingly, the row signals may be sequentially controlled to be boosted to the positive voltage (e.g., pumping voltage VPP) level.

In addition, the image sensing device according to the present disclosure may sequentially activate the voltage control signals (TX_VSSPX_C) for each group (G1~G4) in each exposure period (EXT1, EXT2). Accordingly, the row signals can be controlled to be sequentially boosted to a negative voltage (e.g., pumping voltage VPP) level.

Therefore, the image sensing device according to the present disclosure enables the peak current of the row driver to be reduced by dispersing the boosting timing of the row signals during each exposure period (EXT1, EXT2) as in (A) in the global shutter method.

As is apparent from the above description, the image sensing device based on embodiments of the present disclosure can reduce the settling time of row signals by reducing peak current of the row signals during the global shutter operation.

The embodiments of the present disclosure may provide a variety of effects capable of being directly or indirectly recognized through the above disclosure.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in the present disclosure. Therefore, the scope of the present disclosure should not be limited to the above-described embodiments but should include the equivalents thereof.

What is claimed is:

1. An image sensing device comprising:
a pixel array including a plurality of pixels arranged in a plurality of rows and a plurality of columns and controlled by a row signal; and
a row driver configured to control an activation timing of the row signal based on a control signal,
wherein the row signal has a stepped pulse shape in which the row signal rises stepwise based on a first voltage control signal and falls stepwise based on a second voltage control signal.

2. The image sensing device according to claim 1, wherein the row signal is a transfer signal for transferring photocharges accumulated in a photoelectric conversion element of each pixel to a floating diffusion region.

3. The image sensing device according to claim 1, wherein:
the row signal increases to a level of a first voltage at a first timing where the control signal is activated;
the row signal is boosted from a level of the first voltage to a level of a second voltage at a second timing where the first voltage control signal is deactivated;
the row signal decreases to a level of a third voltage at a third timing where the control signal is deactivated; and
the row signal is boosted from a level of the third voltage to a level of a fourth voltage at a fourth timing where the second voltage control signal is deactivated.

4. The image sensing device according to claim 3, wherein:
the first voltage is a power-supply voltage; and
the second voltage is a pumping voltage having a higher level than the first voltage.

5. The image sensing device according to claim 3, wherein:
the third voltage is a ground voltage; and
the fourth voltage is a back-bias voltage having a lower level than the third voltage.

6. The image sensing device according to claim 3, further comprising a voltage generator configured to generate the first voltage, the second voltage, the third voltage, and the fourth voltage.

7. The image sensing device according to claim 1, wherein the row driver includes:
a first driver configured to be enabled when the control signal is at a first logic level, and configured to control a voltage level of the row signal to have a first voltage or a second voltage based on the first voltage control signal; and
a second driver configured to be enabled when the control signal is at a second logic level, and configured to control the voltage level of the row signal to have a third voltage or a fourth voltage based on the second voltage control signal.

8. The image sensing device according to claim 7, wherein the first driver includes:
a first transistor connected to an input terminal of the first voltage, and controlled by the control signal;
a second transistor connected between the first transistor and a first node, and controlled by an inversion signal of the first voltage control signal;
a third transistor connected to an input terminal of the second voltage, and controlled by the control signal; and
a fourth transistor connected between the third transistor and the first node, and controlled by the first voltage control signal.

9. The image sensing device according to claim 7, wherein the second driver includes:
a fifth transistor connected to an input terminal of the third voltage, and controlled by the control signal;
a sixth transistor connected between the fifth transistor and a first node, and controlled by the second voltage control signal;
a seventh transistor connected to an input terminal of the fourth voltage, and controlled by the control signal; and
an eighth transistor connected between the seventh transistor and the first node, and controlled by an inversion signal of the second voltage control signal.

10. The image sensing device according to claim 1, further comprising a timing controller configured to generate the control signal, the first voltage control signal, and the second voltage control signal.

11. An image sensing device comprising:
a pixel array including a plurality of pixels arranged in a plurality of rows and a plurality of columns and controlled by a plurality of row signals;
a first driver configured to control a voltage level of a first row signal among the plurality of row signals based on a first voltage control signal and a second voltage control signal; and
a second driver configured to control a voltage level of a second row signal among the plurality of row signals based on a third voltage control signal and a fourth voltage control signal,
wherein the first voltage control signal and the third voltage control signal are activated at different timings, and the second voltage control signal and the fourth voltage control signal are activated at other different timings.

12. The image sensing device according to claim 11, wherein:
the first driver includes a plurality of driver circuits grouped into a first group; and
the second driver includes a plurality of driver circuits grouped into a second group.

13. The image sensing device according to claim 11, wherein:
each of the first row signal and the second row signal is a transfer signal for transferring photocharges accumulated in a photoelectric conversion element of each pixel to a floating diffusion region.

14. The image sensing device according to claim 11, wherein:
each of the first row signal and the second row signal increases to a level of a first voltage at a first timing where a control signal is activated;
the first row signal is boosted from a level of the first voltage to a level of a second voltage at a second timing where the first voltage control signal is deactivated;
the second row signal is boosted from the level of the first voltage to the level of the second voltage at a third timing where the third voltage control signal is deactivated;
each of the first row signal and the second row signal decreases to a level of a third voltage at a fourth timing where the control signal is deactivated;
the first row signal is boosted from a level of the third voltage to a level of the fourth voltage at a fifth timing where the second voltage control signal is deactivated; and
the second row signal is boosted from the level of the third voltage to the level of the fourth voltage at a sixth timing where the fourth voltage control signal is deactivated.

15. The image sensing device according to claim 14, wherein:
the first voltage is a power-supply voltage, and the second voltage is a pumping voltage having a higher level than the first voltage; and
the third voltage is a ground voltage, and the fourth voltage is a back-bias voltage having a lower level than the third voltage.

16. The image sensing device according to claim 14, further comprising a voltage generator configured to generate the first voltage, the second voltage, the third voltage, and the fourth voltage.

17. The image sensing device according to claim 11, wherein the first driver includes:
a first driver circuit configured to be enabled when the control signal is at a first logic level, and configured to control a voltage level of the row signal to have a first voltage or a second voltage based on the first voltage control signal; and
a second driver circuit configured to be enabled when the control signal is at a second logic level, and configured to control the voltage level of the row signal to have a third voltage or a fourth voltage based on the second voltage control signal.

18. The image sensing device according to claim 17, wherein the first driver circuit includes:
a first transistor connected to an input terminal of the first voltage, and controlled by the control signal;
a second transistor connected between the first transistor and a first node, and controlled by an inversion signal of the first voltage control signal;
a third transistor connected to an input terminal of the second voltage, and controlled by the control signal; and
a fourth transistor connected between the third transistor and the first node, and controlled by the first voltage control signal.

19. The image sensing device according to claim 17, wherein the second driver circuit includes:
a fifth transistor connected to an input terminal of the third voltage, and controlled by the control signal;
a sixth transistor connected between the fifth transistor and a first node, and controlled by the second voltage control signal;
a seventh transistor connected to an input terminal of the fourth voltage, and controlled by the control signal; and
an eighth transistor connected between the seventh transistor and the first node, and controlled by an inversion signal of the second voltage control signal.

20. The image sensing device according to claim 11, further comprising a timing controller configured to selectively activate the first voltage control signal, the second voltage control signal, the third voltage control signal, and the fourth voltage control signal.
